(19) United States
(12) Patent Application Publication
(10) Pub. No.: US 2009/0108452 A1
(43) Pub. Date: Apr. 30, 2009

(54) Semiconductor device and method for manufacturing the same

(75) Inventors: Takenao Nemoto, Sendai (JP); Akinobu Teramoto, Sendai (JP); Tadahiro Ohmi, Sendai (JP)

Correspondence Address: MASUVALLEY & PARTNERS, 8765 AERO DRIVE, SUITE 312, SAN DIEGO, CA, 92123, US

(73) Assignees: Tokyo Electron Limited, Minato-ku (JP); Tohoku University, Sendai (JP)

(21) Appl. No.: 12/290,589

(22) Filed: Oct. 31, 2008

(30) Foreign Application Priority Data
Oct. 31, 2007 (JP) JP2007-283659

(51) Int. Cl. H01L 23/52; H01L 21/4763

(52) U.S. Cl. 257/751; 438/643; 257/E23.141; 257/E21.495

(57) ABSTRACT

A method of manufacturing a semiconductor device including a sputtering process for forming a barrier film mainly having tantalum or tantalum nitride on an interlayer insulator formed by sputtering using a xenon gas. The sputtering process may include a step of forming one barrier film mainly composed of tantalum nitride on a substrate by sputtering using a xenon gas by applying a RF bias, and a step for forming another barrier film mainly composed of tantalum on the first barrier film by sputtering using a xenon gas without applying the RF bias. The barrier film may be formed by changing the RF bias continuously, and forming the interlayer insulator side by applying the RF bias, and forming the wiring side without applying the RF bias.

### TECHNICAL FIELD

The present invention relates to a semiconductor device and a method for manufacturing the same. More specifically, the present invention relates to a semiconductor device provided with a barrier film between a wiring and an insulator under the wiring, and a method for manufacturing the semiconductor device in which the barrier film is formed by sputtering.

### BACKGROUND OF THE INVENTION

In today's semiconductor integrated circuit devices, a multi-layer wiring structure, in which wiring layers having a wiring pattern buried in an interlayer insulator are stacked, has been used in many cases to connect a number of elements formed on a substrate. The performance of integrated circuits has progressed along with high-integration due to miniaturization of devices, and an increase of the operating frequency. The density growth along with the miniaturization of these devices, the operating delay time of integrated circuits is not only the gate delay time for a transistor, which is the core, but also relatively increasing the ratio of the RC delay time determined from the resistance R of the wiring times the line capacity C. For this reason, a low-resistance copper is used to decrease the resistance of the wiring, and a low-permittivity interlayer insulator (so called a low-K interlayer insulator) is used to decrease capacity between wirings. And a barrier layer is formed between the wiring and interlayer insulator to prevent the copper in the wiring from diffusing to the interlayer insulator.

As a barrier layer, molybdenum (Mo), tantalum (Ta), or tantalum nitride (TaN) etc. has been used (for example, refer to Japanese Unexamined Patent Application Publication No. 2005-347472). To deposit these metals by sputtering, Ar gas has been used (refer to Japanese Unexamined Patent Application Publication Nos. 2001-85331, 2003-309084). However, “when a physical vapor deposition (PVD) method, such as sputtering, is used, there is a possibility that the Ta/TaN diffuses to each of the interlayer insulators because the particles that are rammed by the PVD are high in energy so that the particles are impinged into interlayer insulators” (refer to paragraph [0054] in Japanese Unexamined Patent Application Publication No. 2005-229093).

Meanwhile, fluorocarbon (CF) has been attracting attention as a low dielectric constant interlayer insulator. However, the fluorocarbon has some drawbacks regarding the process consistency, such as, low adhesiveness. (Preparation of Low-Dielectric Constant Films Using Fluorocarbon Plasma CVD (<Special Topic Article> Fluorocarbon Plasmas Used for Materials Processing Current Status and Issues):(Refer to Journal of Plasma and Fusion Research Vol. 83. No. 4(20070425) pp. 350-355)).

The argon (Ar) plasma generally used for sputtering is high in plasma potential, and also high in energy transfer efficiency against the fluorocarbon (CF), thus it is likely to damage a CF substrate. Meanwhile, the Ar plasma is low in energy transfer efficiency against tantalum nitride (TaN), thus the energy for improving crystallinity is less likely to be given (the energy sufficient for improving crystallinity is not given). As a result, TaN with a favorable crystallinity can not be formed on the CF substrate.

The present invention has been made considering the above situations, and an objective is to provide a method for manufacturing a semiconductor device, in which a barrier film mainly consisting of tantalum (Ta) is sputtered while suppressing the damage to an interlayer insulator.

### SUMMARY OF THE INVENTION

In accordance with one aspect of the present invention, a semiconductor device includes:

a first layer located over a semiconductor substrate,

a barrier film formed on the first layer, the barrier film including tantalum (Ta) and xenon (Xe), and

a second layer located on the barrier film,

where the barrier film suppresses atoms from passing between the first and second layers.

According to this aspect of the present invention, a semiconductor device having a barrier film containing tantalum and also having the damage-suppressed first layer can be provided. Further, the barrier property can be secured against the diffusion of atoms between the first layer and second layer.

The first layer may be an insulating layer, and the second layer may be a conductive layer. Further, the second layer may include copper (Cu), or the first layer may be selected from a group consisting of silicon dioxide (SiO₂), fluorocarbon (CF) and carbon added silicon oxide (SiOC).

According to this aspect, a semiconductor device having a barrier film containing tantalum can be provided while avoiding the damage to the insulating layer. Further, the barrier property can be secured against the copper contained in the second layer from diffusing to the insulating layer.

The semiconductor device may include:

a silicon carbonnitride (SiCN) layer located between the first layer and the barrier film. Further, the first layer may include fluorocarbon (CF).

According to this aspect, the carbon (C) and fluorine (F) contained in the first layer can be prevented from diffusing to the barrier film. Further, the adhesiveness of the second layer and barrier film is improved.

The barrier film may include:

a lower barrier film portion formed on the first layer by sputtering using a xenon (Xe) gas with an RF bias applied to the semiconductor substrate, the lower barrier film portion comprising a tantalum nitride (TaN); and

an upper barrier film portion formed on the second layer by sputtering using the xenon (Xe) gas without the RF bias applied to the semiconductor substrate or with less RF bias than is applied when forming the lower barrier film portion, the lower barrier film portion comprising a tantalum nitride (TaN).

According to this aspect, the lower barrier film with high crystallinity is high in a barrier property. And the upper barrier film with low crystallinity is high in adhesiveness with the second layer. For this reason, the barrier property can further be improved between the first and second layers against the diffusion of atoms, and also the adhesiveness between the second layer and the barrier film can be increased.

The barrier film may include:

a lower barrier film portion formed on the first layer by sputtering using a xenon (Xe) gas with an RF bias applied to the semiconductor substrate, the lower barrier film portion comprising a tantalum nitride (TaN); and

an upper barrier film portion formed on the second layer by sputtering using the xenon (Xe) gas without the RF bias applied to the semiconductor substrate or with less RF bias than is applied when forming the lower barrier film portion, the lower barrier film portion comprising a tantalum (Ta).

According to this aspect, the lower barrier film with high crystallinity is high in a barrier property. And the upper barrier film with low crystallinity is high in adhesiveness with the second layer. For this reason, the barrier property can further be improved between the first and second layers against the diffusion of atoms, and also the adhesiveness between the second layer and the barrier film can be increased.

In accordance with one aspect of the present invention, a semiconductor device includes:

a first insulating layer located over a silicon substrate,

a first interconnection pattern located in the first insulating layer,

a second insulating layer located on the first insulating layer,

a via plug located in a lower part of the second insulating layer that includes copper (Cu) and is electrically connected to the first interconnection pattern,

a second interconnection pattern located in an upper part of the second insulating layer that includes copper (Cu) and is electrically connected to the via plug, and

a barrier film located between the second insulating layer and at least one of the via plugs and the second interconnection pattern,

where the barrier film includes tantalum (Ta) and xenon (Xe).

According to this aspect of the present invention, a semiconductor device having a barrier film containing tantalum and also having the damage-suppressed second insulating layer can be provided. Further, the barrier property can be secured against the copper (Cu) contained in the via plug or the second wiring pattern from diffusing to the second insulating layer.

The semiconductor may include:

a silicon carbonitride (SiCN) layer located between the second insulating layer and the barrier film. Further, the second insulating layer may include a low-k material. Further, the second insulating layer may include fluorocarbon (CF).

According to this aspect, the carbon (C) and fluorine (F) contained in the second insulating layer can be prevented from diffusing to the barrier film. Further, the adhesiveness of the via plug or the second wiring pattern and the barrier film is improved.

The barrier film may contain nitrogen (N). Further, a number of nitrogen atoms in the barrier film may gradually increase through a thickness of the barrier film.

According to this aspect, one side of the barrier film is high in crystallinity with low nitrogen concentration, and the other side of the barrier film is low in crystallinity with high nitrogen concentration. The barrier property can further be improved against the copper (Cu) contained in the via plug or in the second wiring pattern from diffusing to the second insulating layer, and also the adhesiveness between the via plug or the second wiring pattern, or the second insulating layer and barrier film can be increased.

In accordance with one aspect of the present invention, a manufacturing method for a semiconductor device includes the steps of:

forming a first layer over a semiconductor substrate,

forming a barrier film on the first layer that includes tantalum (Ta), and

forming a second layer on the barrier film,

where the barrier film is formed by sputtering using xenon (Xe) gas.

According to this aspect of the present invention, a barrier film containing tantalum can be formed while avoiding the damage to the first layer. Further, the barrier property can be secured against the diffusion of atoms between the first and second layers.

The barrier film may be formed with an RF bias applied to the semiconductor substrate. Further, a peak voltage of the RF bias may be more than 0V and less than or equal to 20V.

According to this aspect, a barrier film with a high crystallinity can be formed. The first layer may include fluorocarbon (CF). According to this aspect, the carbon (C) and fluorine (F) contained in the first layer can be prevented from diffusing to the second layer.

The manufacturing method may include the step of

forming a silicon carbonitride (SiCN) layer on the first layer after forming the first layer before forming the barrier film.

According to this aspect, the adhesiveness of the second layer and barrier film improves.

Forming the barrier film may include:

forming a lower barrier film on the first layer with an RF bias applied to the semiconductor substrate,

forming an upper barrier film on the lower barrier film without the RF bias applied to the semiconductor substrate or with less RF bias than is applied in forming the lower barrier film to the semiconductor substrate.

According to this aspect, the lower barrier film with high crystallinity is high in a barrier property. And the upper barrier film with low crystallinity has high adhesiveness to the second layer due to. For this reason, the barrier property can further be improved against the diffusion of atoms between the first and second layers, and the adhesiveness between the second layer and the barrier film can also be improved.

### BRIEF DESCRIPTION OF THE DRAWINGS

FIG. 1A illustrates a forming process of a wiring layer in a semiconductor device pertaining to an embodiment of the present invention, and is a cross section diagram in which a wiring pattern is formed on a substrate.

FIG. 1B is a cross section diagram of a substrate in which an interlayer insulator is formed on a wiring pattern.

FIG. 1C is a cross section diagram of a substrate in which a barrier film is formed on the interlayer insulator.

FIG. 1D is a cross section diagram of a substrate in which a depressed section is filled with a conductor.

FIG. 2 is a block diagram illustrating a configuration of a plasma treatment apparatus used in an embodiment.

FIG. 3 is a cross section diagram illustrating a barrier film formed in a two-step process.

FIG. 4 is a cross section diagram illustrating a case where a sputtering is performed by changing a RF bias continuously.

FIG. 5 illustrates a crystal orientation of TaN in cases when a RF bias is applied and when the RF bias is not applied.

FIG. 6 illustrates a binding energy of N in TaN in cases when a RF bias is applied and when the RF bias is not applied.

FIG. 7 illustrates a binding energy of Ta in TaN in cases when a RF bias is applied and when the RF bias is not applied.

FIG. 8 illustrates energy transfer efficiencies for combinations of ions and substrates.

FIG. 9 illustrates an example of a transfer energy Eion and a biding energy.

FIG. 10 illustrates a SIMS analysis before annealing in a case when Cu is formed on TaN, which is formed on a thermally-oxidized silicon film by applying a RF bias.

FIG. 11 illustrates a SIMS analysis after annealing in a case when Cu is formed on TaN, which is formed on a thermally-oxidized silicon film by applying a RF bias.

FIG. 12 illustrates a SIMS analysis before annealing in a case when Cu is formed on TaN, which is formed on a thermally-oxidized silicon film without applying a RF bias.

FIG. 13 illustrates a SIMS analysis after annealing in a case when Cu is formed on TaN, which is formed on a thermally-oxidized silicon film without applying a RF bias.

FIG. 14 illustrates a SIMS analysis before annealing in a case when Cu is formed on TaN, which is formed on a fluorocarbon film by applying a RF bias.

FIG. 15 illustrates a SIMS analysis after annealing in a case when Cu is formed on TaN, which is formed on a fluorocarbon film by applying a RF bias.

FIG. 16 illustrates a SIMS analysis before annealing in a case when Cu is formed on TaN, which is formed on a fluorocarbon film without applying a RF bias.

FIG. 17 illustrates a SIMS analysis after annealing in a case when Cu is formed on TaN, which is formed on a fluorocarbon film without applying a RF bias.

FIG. 18 illustrates a SIMS analysis before annealing in a case when Cu is formed on TaN, which is formed on a silicon carbonitride/fluorocarbon stacked film by applying a RF bias.

FIG. 19 illustrates a SIMS analysis after annealing in a case when Cu is formed on TaN, which is formed on a silicon carbonitride/fluorocarbon film by applying a RF bias.

FIG. 20 illustrates an examination result for adhesiveness of a fluorocarbon substrate.

### DETAILED DESCRIPTION OF INVENTION

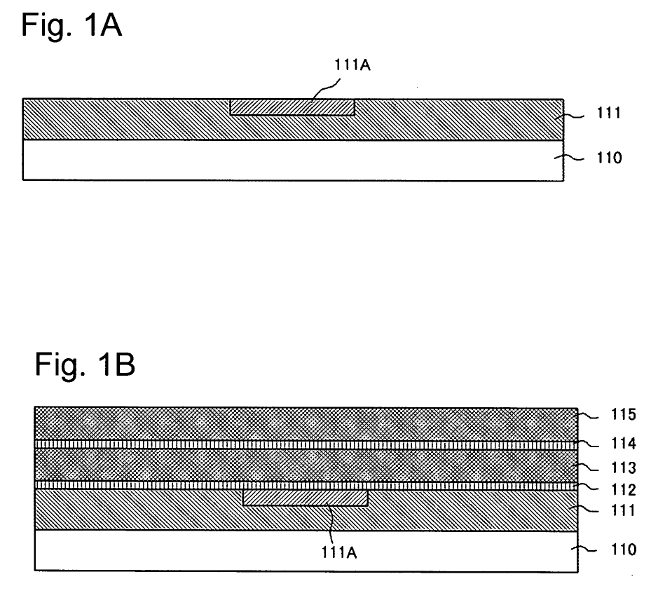

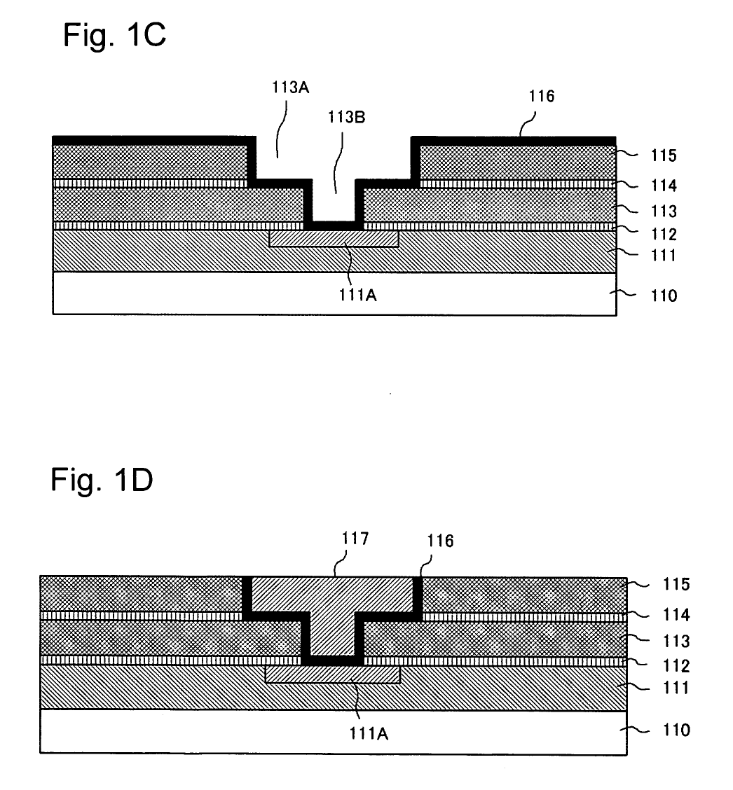

Embodiments of the present invention will be explained in detail with reference to the drawings. FIGS. 1A through 1D illustrate a forming process of a wiring layer in a semiconductor device pertaining to an embodiment of the present invention.

FIG. 1A is a cross section diagram in which a wiring pattern is formed on a substrate. Onto a silicon oxide film (SiO₂ film) 111 formed on a silicon substrate 110, a wiring pattern 111A formed from a low resistance metal, such as, copper (Cu), and is buried. FIG. 1B is a cross section diagram of a substrate, in which an interlayer insulator is formed on the wiring pattern. In the process of FIG. 1B, a low-permittivity interlayer insulator 113, an etching stopper film 114, such as SiN film, and a low-permittivity interlayer insulator 115 are formed on the SiO₂ film 111 via an etching stopper film 112, such as silicon nitride film (SiN film).

For example, SiO₂, fluorocarbon (CF), carbon added silicon oxide (SiOC) or silicon carbonitride (SiCN) may be used for the interlayer insulators 113 and 115. Alternatively, a film such as a thin film of SiCN formed on fluorocarbon (CF), may also be used. The fluorocarbon has fluorine (F) and carbon (C) as main components. The fluorocarbon with an amorphous (noncrystalline) structure may be used. The interlayer insulator may have a porous structure, such as, carbon added silicon oxide (SiOC).

FIG. 1C is a cross section diagram of a substrate in which a barrier layer is formed on an interlayer insulator. In the process of FIG. 1C, depressed sections 113A and 113B, such as a wiring groove or a via hole, are formed in the interlayer insulators 113 and 115. A SiN film 114 is formed as an etching stopper film so as to expose the surface of Cu wiring pattern 111A at the bottom of the via hole 113B. Further, in the process of FIG. 1C, a barrier film 116 is formed so as to cover the bottom face and the side wall face of the depressed sections 113A and 113B on the structure of FIG. 1B.

The barrier film 116 is formed with tantalum (Ta) or tantalum nitride (TaN) as a main component. The barrier film 116 is formed by depositing Ta by sputtering in a plasma of xenon (Xe) gas. To deposit the barrier film of tantalum/tantalum nitride, a process gas contains Xe and nitrogen. The Xe works as a main gas source for a plasma ion and impacts a target, and the nitrogen forms a tantalum/tantalum nitride film which is deposited on the substrate by reacting the atoms (tantalum) mainly sputtered from the target. As a result of sputtering by using the Xe gas, a deposited barrier film contains a slight amount of Xe atoms.

FIG. 1D is a cross section diagram of a substrate in which the depressed sections 113A and 113B are filled with conductors. An excess Cu film on the interlayer insulator 115 and barrier film 116 on an upper face of the interlayer insulator are polished and removed by the CMP method (Chemical Mechanical Polishing) after filling the depressed sections 113A and 113B with, for example, a Cu film on the barrier layer 116 in the process of FIG. 1D. As shown in FIG. 1D, the depressed sections 113A and 113B are filled with Cu material, thereby a structure of the wiring layer 117, such as a Cu wiring pattern or a Cu plug, can be obtained.

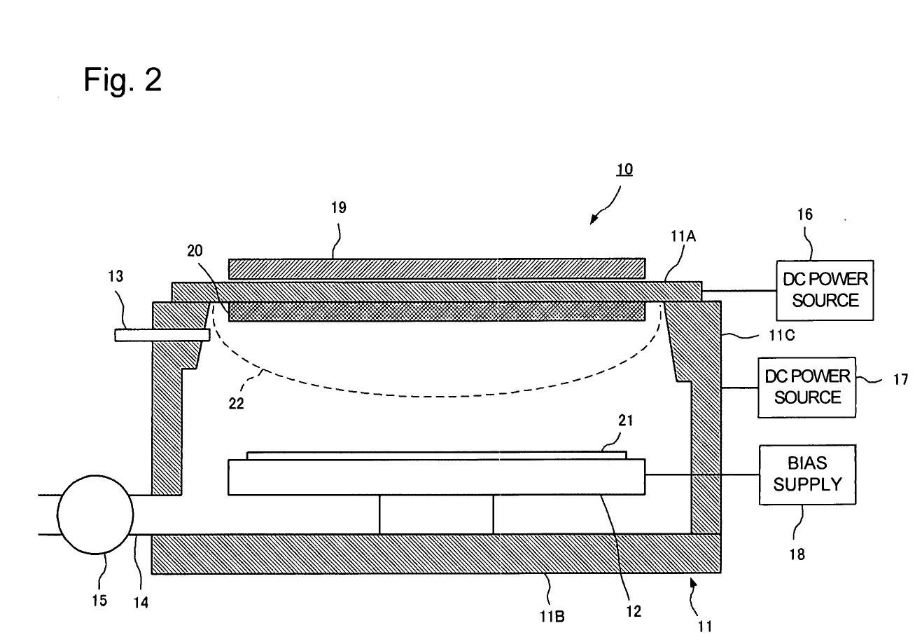

FIG. 2 illustrates a configuration of a plasma treatment apparatus 10 used in the embodiment. The plasma treatment apparatus 10 stores a substrate holding table 12 holding a processing substrate 21, and includes a treatment container 11 which forms a process space with the substrate holding table 12. The treatment container 11 is formed of a target holding table 11A, base 11B and side wall 11C. The target holding table 11A is holds a target 20 and a magnet 19 is arranged on the opposite side of the target 20. The treatment container 11 is provided with a gas inlet 13 and an exhaust duct 14. The exhaust duct 14 is connected to a pump 15.

The target holding table 11A is connected to a DC power source 16. Normally, the DC power source 16 retains the target holding table 11A to a positive electric potential against the substrate holding table 12. The side wall 11C has a conductive property and is connected to the DC power source 17. The DC power source 17 retains the side wall 11C to a negative electric potential against the substrate holding table 12. The substrate holding table 12 is also connected to a RF bias supply 18. The RF bias supply 18 applies a high-frequency alternate voltage to the substrate holding table 12 against the target 20. Thereby, a RF bias is applied to the processing substrate 21.

Inside the treatment container 11 is retained in an adequate vacuum by the pump 15. Xe gas is introduced from the gas inlet 13 and a plasma 22 is generated by the glow discharge etc. (not shown). The plasma 22 is confined around the target 20 by the magnet 19. Here, there are cases where the RF bias is applied to the processing substrate 21 by the RF bias supply 18 and the RF bias is not applied to the processing substrate 21. Electrons generated in the lower layer of and around the plasma 22 are flown from the conductive side wall 11C to the DC power source 17. As a result, the ion concentration in the plasma 22 increases. The target 20 is retained in a negative electric potential. And the ions of plasma 22 collide on the target 20 and the atoms of the target are sputtered. The sputtered atoms are deposited to the substrate 21 and form a film.

In the present invention, tantalum Ta, or a Ta alloy or a Ta compound mainly consisting of Ta is used as the target 20. Further, nitrogen N etc. is introduced from the gas inlet 13 as needed. The nitrogen N reacts with the atoms (tantalum) mainly sputtered from the target 20 and forms the tantalum/tantalum nitride film deposited on the substrate.

When forming a barrier film of Ta/TaN with the plasma treatment apparatus 10, there are methods in which the sputtering is performed by applying the RF bias and the sputtering is performed without applying the RF bias. In the both cases, the damage to the interlayer insulator is smaller compared to a case when Ar is used. Especially, the damage to the interlayer insulator is smaller than the Ar in the case of fluorocarbons.

Though the detail is described later, Ta/TaN shows a tendency of relatively high crystallinity when the RF bias is applied and Ta/TaN shows a tendency of relatively low crystallinity when the RF bias is not applied. And the barrier property of Cu is high in the high crystalline Ta/TaN, and the adhesiveness to Cu is high in the low crystallinity Ta/TaN. Depending on the combination of the interlayer insulator and wiring layer, the Ta/TaN sputtered with a Xe plasma while applying the RF bias, or Ta/TaN sputtered with Xe plasma without applying the RF bias may be used as a barrier film.

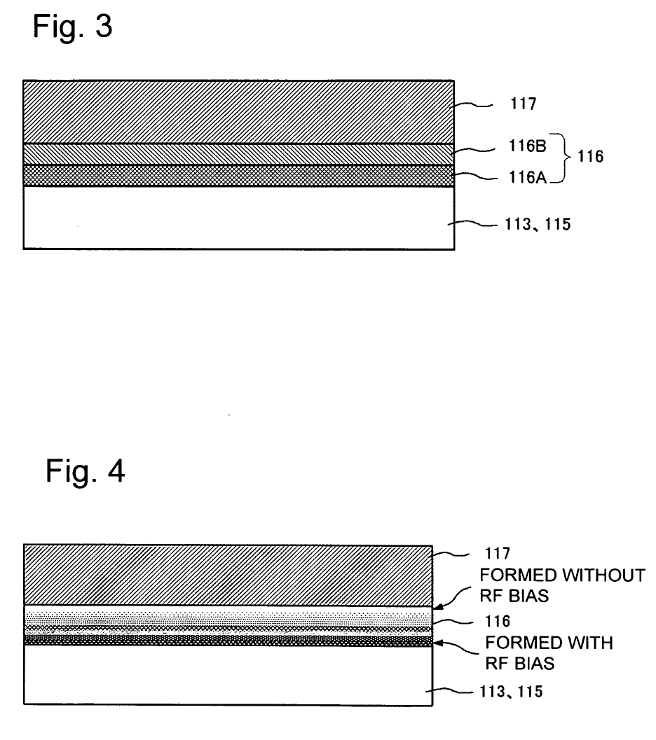

When the barrier film on the side that contacts the interlayer insulator is formed by applying the RF bias, and the barrier film on the side that contacts the wiring without applying the RF bias, a barrier film that is high in a barrier property of Cu and high in adhesiveness to the Cu can be obtained. FIG. 3 is a cross-section diagram illustrating a barrier film formed in a two-stage process. A Ta/TaN barrier film 116A is formed by applying the RF bias to the side where the interlayer insulators 113 and 115 contact. And a Ta/TaN barrier film 116B is formed over the barrier film 116A without applying the RF bias. In this case, the films are formed by the sputtering of the Xe gas, thus a slight mount of Xe is contained. In this way, the barrier property that prevents the Cu in the wiring layer 117 from diffusing to the interlayer insulators 113 and 115 is further improved, and the adhesiveness of the Cu and barrier film 116B can further be increased.

Similar effects can be achieved by performing sputtering by changing the RF bias continuously instead of forming the barrier film in a clear two-layer structure as shown in FIG. 3. FIG. 4 is a cross section diagram illustrating a case where Ta/TaN is deposited by sputtering changing the RF bias continuously.

It may be such that the interlayer 113 and 115 sides are sputtered by applying the RF bias, and the wiring layer 117 side is sputtered without the RF bias or by applying a smaller RF bias than on the interlayer insulator 113 and 115 sides. This also enables the formation of a barrier film with improved barrier properties and increased adhesiveness.

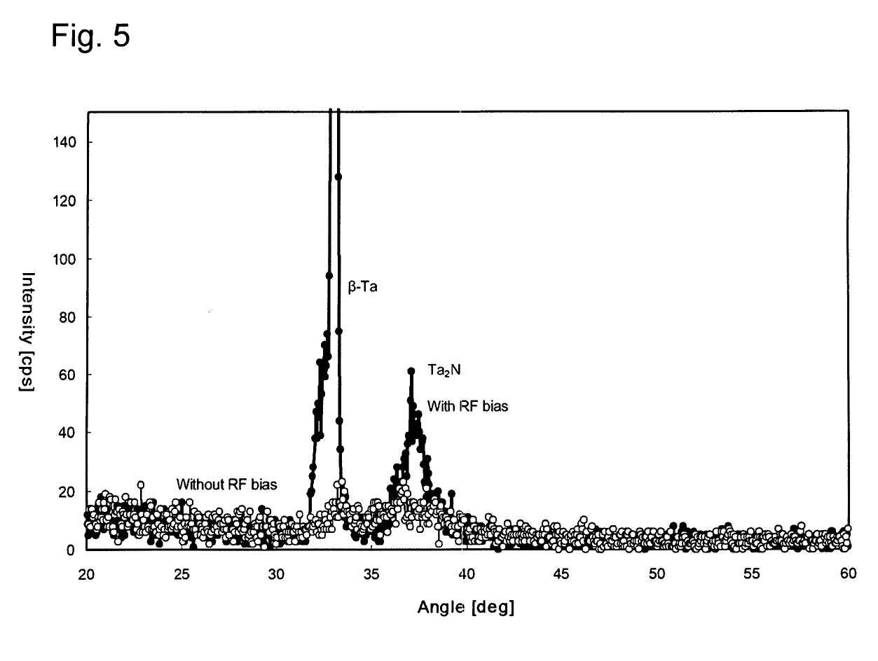

FIG. 5 illustrates the scattering intensity (diffraction pattern) (Intensity) of TaN in cases of applying the RF bias and without applying the RF bias. The black circle bold line indicates the scattering intensity of the crystal in a case when performing sputtering with Xe by applying the RF bias. The white circle thin line indicates the scattering intensity of the crystal orientation in a case when performing sputtering with Xe without the RF bias. It can be noted that significant peaks for β-Ta and Ta₂N appeared, and the crystal structures of these β-Ta and Ta₂N are formed when the RF bias is applied. Without the RF bias, such a peak hardly appears, which indicates that the crystallinity is low. It can be noted that the crystallinity of TaN increases by the ion collisions due to the RF bias even when the plasma potential of the Xe plasma is low.

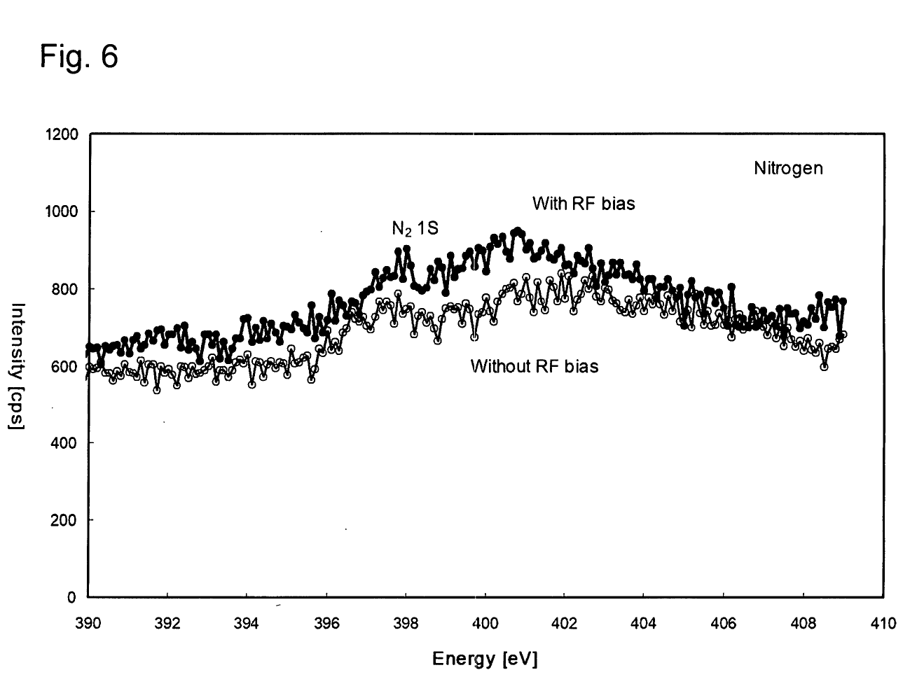

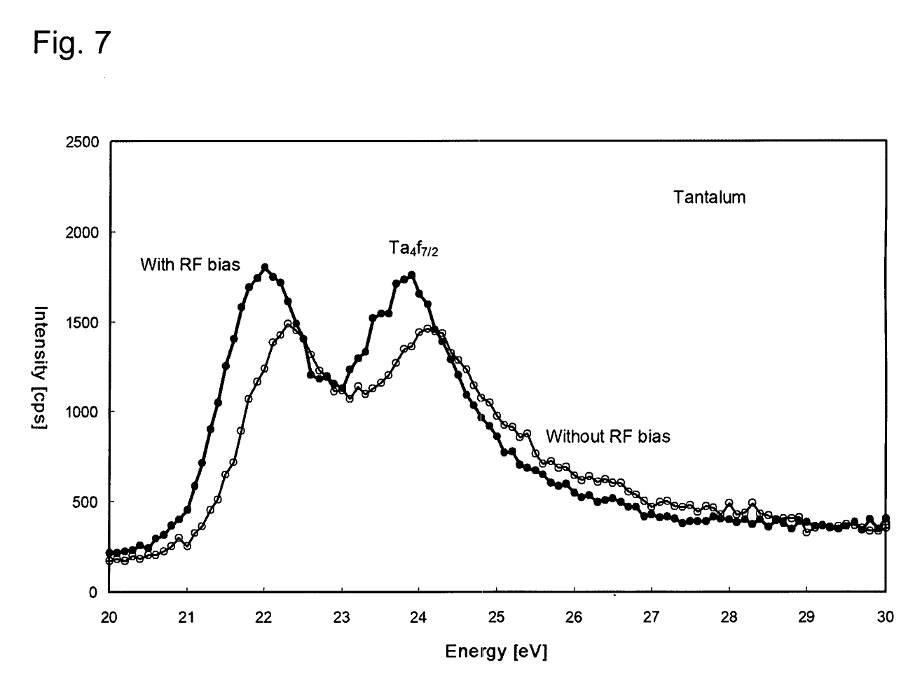

FIGS. 6 and 7 illustrate bonding energy for each N and Ta in TaN in cases when the RF bias is applied and without applying the RF bias. FIG. 6 is a graph of nitrogen N and FIG. 7 is a graph of tantalum (Ta). The binding energy is measured by X-ray Photoelectron Spectroscopy (hereinafter referred as XPS). In the FIGS. 6 and 7, the black circle bold line indicates the case when performing sputtering with Xe by applying the RF bias and the white circle thin line indicates the case when performing sputtering with Xe without the RF bias.

As shown FIG. 6, the peak intensity of N₂1S is relatively higher in each graph for the TaN without the RF bias compared to the case of applying the RF bias. Therefore, this means that more nitrogen atoms are taken to the TaN in the case of no RF bias compared to the case of applying the RF bias.

This is also backed by the FIG. 7. That is, because more nitrogen atoms are taken in, Ta₄f_{7/2}, which is the peak of Ta, is shifted to high energy in the case of no RF bias. As a result, a TaN thin film with low nitrogen concentration and high crystallinity is formed by the Xe sputtering while applying the RF bias, and a TaN thin film with more nitrogen atoms and low crystallinity is formed by the Xe sputtering without applying the RF bias.

Assuming the simple mass system collision of ideal particles, the energy transfer efficiency η of an ion that collides with an atom on the substrate can be given by the following formula (1).

$$\begin{matrix}[ Formula 1 ] & \\ η = \frac{4 Mion / M sub}{{( 1 + Mion / Msub )}^{2}} & ( 1 )\end{matrix}$$

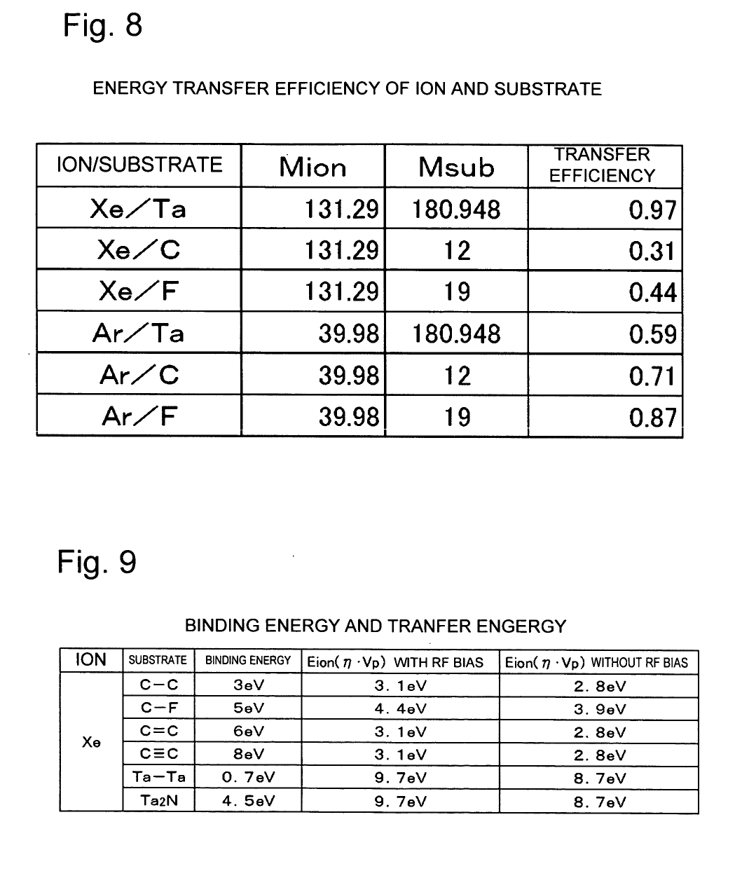

Here, Mion is the atomic mass of an ion and Msub is the atomic mass of the substrate. FIG. 8 shows results of energy transfer efficiencies for combinations of several types of ions and substrates from formula (1) and atomic masses. As shown in the table of FIG. 8, the energy transfer efficiencies from an Xe ion to Ta, C and F are 97%, 31%, and 44% respectively. Compared to the transfer efficiency of 59% from an Ar ion to Ta, most of the energy is transferred from Xe to Ta. Meanwhile, only a small amount of energy transfers from an Xe ion to C and F atoms. On the contrary, in the case of an Ar ion, more energy transfers to C (71%) and F (87%) compared to Ta (59%).

Although the collision energy of an ion is necessary to crystallize the thin film deposited on a substrate, the collision also damages the substrate. Therefore, the Xe ion, where more energy is transferred to Ta and only less energy transfers to C and F atoms, is favorable for forming a Ta barrier film on the substrate.

The transfer energy of an ion is given by the following formula (2):

Eion=η·Vion (2)

Here, the Vion is the energy of an ion at a substrate in a plasma, and is called a floating potential. The floating potential is the alternating-current component of the voltage that is being applied. FIG. 9 shows the binding energy and transfer energy (Eion) for some substrates (W. Shindo and T. Ohmi: J. Appl. Phys., 79(5), (1996), 2347). In FIG. 9, the ion is Xe. Shown are the cases where the substrate is a single bond of carbon, a single bond of carbon and fluorine, a double bond of carbon, a triple bond of carbon, Ta and Ta₂N.

As shown in FIG. 9, the binding energies for C and F are equivalent to Eion or higher in both cases. Therefore, it can be thought that these substrates will not be damaged in the Xe plasma. On the other hand, as for Ta and Ta₂N, the Eions are larger compared to the bonding energy; however it is thought that the energy necessary to crystallize is given by the Xe plasma.

As for Ta, the difference in Eion is 1.0 eV in cases of applying the RF bias and not applying the RF bias. This difference is thought to be affecting the crystallization of TaN. The Ar plasma is a high density plasma showing higher energy in about 10 eV compared to the Xe, and damages the fluorocarbon substrate due to its high energy transfer efficiency to the substrate as shown in FIG. 8.

When Vion=20V in formula (2), Eion=transfer efficiency·Vion=0.31×20 eV=6.2 eV for carbon C. In the case of double bond of carbon, the binding energy is 6 eV (refer to FIG. 9). Thus, the RF bias of 20V is effective to the material that has the double bond of carbon. Therefore, 0 to 20V is adequate for the RF bias applied to the plasma treatment device 10.

In the following concrete examples, the barrier film of Ta/TaN is sputtered on each type of interlayer insulator with the Xe plasma. In the concrete examples, the wiring layer of Cu is formed on the barrier film. Without being limited to Cu, aluminum, tin, indium etc. or an alloy of these may be used for the wiring layer.

### EXAMPLE 1

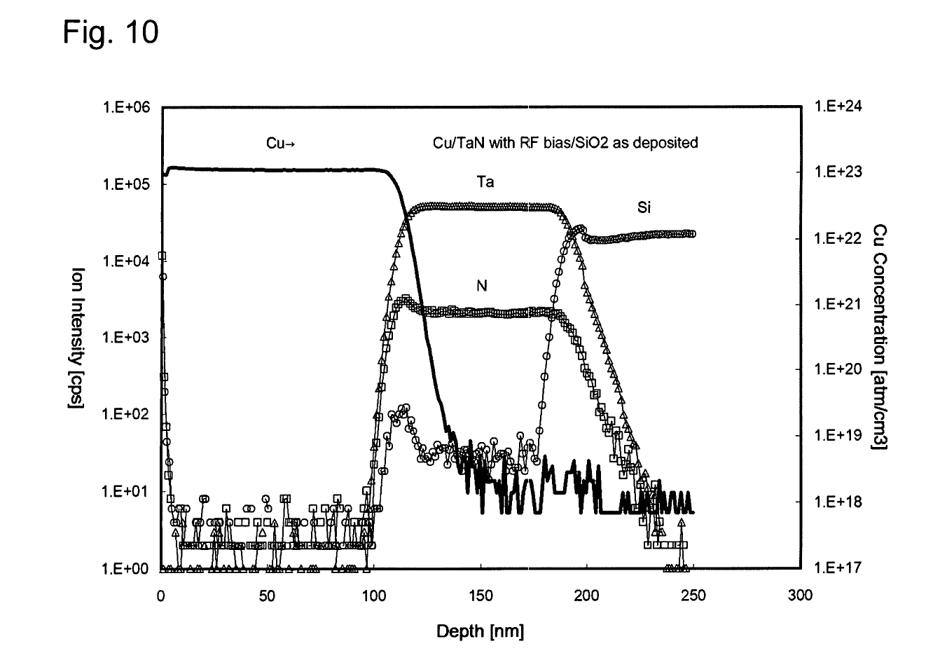

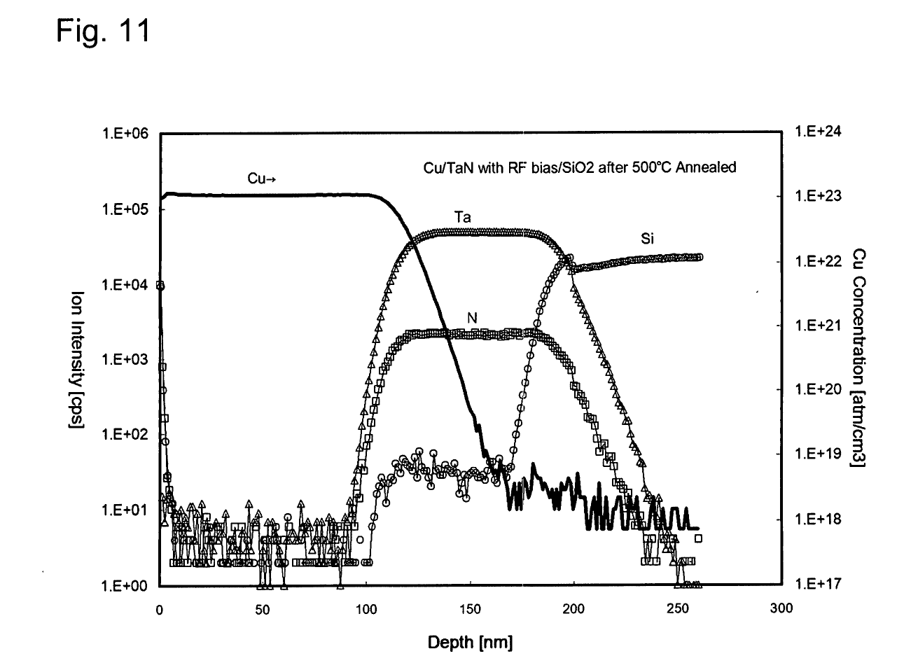

FIGS. 10 and 11 illustrate analyses in depth directions by SIMS (Secondary Ion Mass Spectrometry) in a case when forming Cu on the TaN which is formed by applying the RF bias on a silicon thermally-oxidized film. The horizontal axis is the depth from the surface, and the vertical axis is the ion intensity (cps). FIG. 10 is the analysis before annealing, and FIG. 11 is the depth direction analysis after annealing the same substrate at 500° C. for an hour. In FIGS. 10 and 11, Cu shows the Cu atomic concentration (Cu Concentration)(atm/cm³) and its scale is indicated by the vertical axis on the right. The scale of ion intensity for other atoms is given by the vertical axis on the left.

In the figures, the solid bold line is the Cu concentration, the white triangle is Ta, the white square is N, and the white circle is Si. As shown in FIGS. 10 and 11, left of the figure is the surface layer and the configurations of Cu, Ta/TaN, and thermal-oxidized silicon films are shown in the direction of increasing depth from the surface layer towards the right. The concentration of Cu atom in the Si is a smaller value by five digits compared to that in the surface layer, thus it is in a noise level in the analysis and can be considered non-existent.

Even after the annealing, the Cu atom hardly diffuses to TaN layer, and does not reach Si. In this way, the TaN formed with the Xe plasma by applying the RF bias effectively prevents the Cu from diffusing to the interlayer insulator.

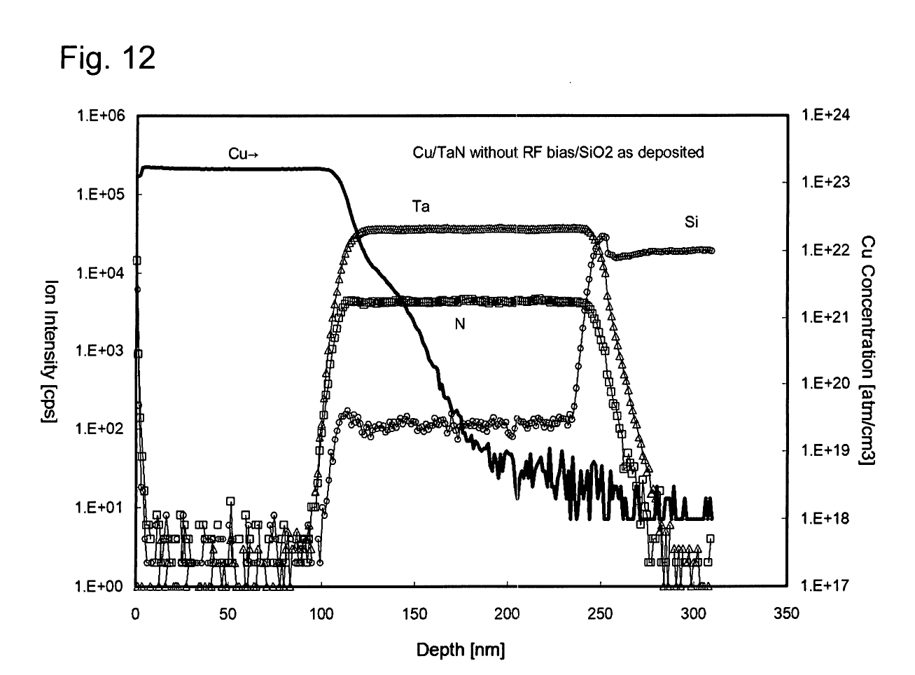

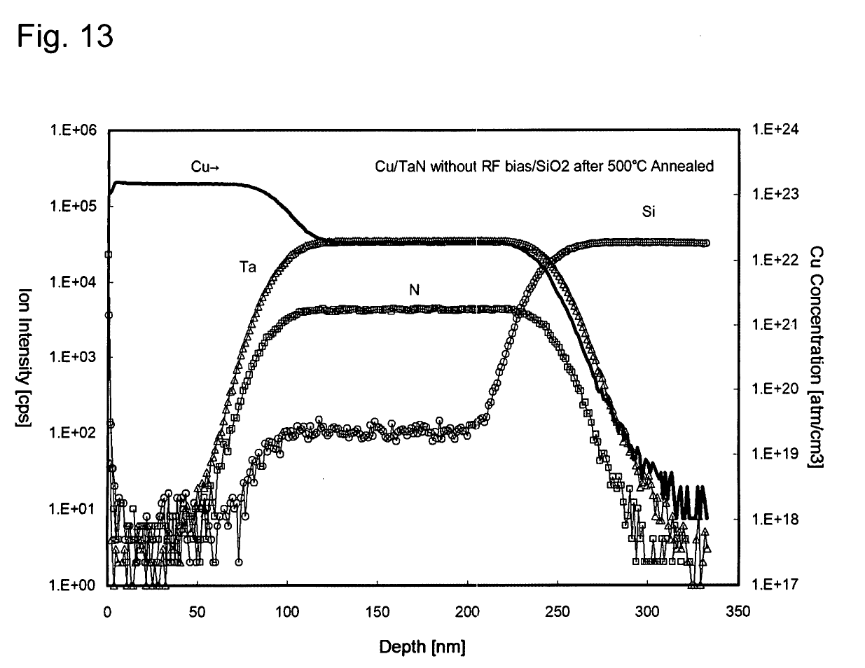

FIGS. 12 and 13 illustrate SIMS analyses in a case when Cu is formed on the TaN formed on a thermally-oxidized silicon film without applying the RF bias. FIG. 12 is the analysis before the annealing, and FIG. 13 is the analysis after being annealed at 500° C. for an hour. Each of the symbols and scales for the ion intensity and atomic concentration are the same as FIG. 10.

As shown in FIG. 12, the Cu diffuses to the TaN even before the annealing compared to FIG. 10. After the annealing, the Cu diffuses to the thermally-oxidized silicon film through the TaN layer formed without applying the RF as shown in FIG. 13.

As a result of the above, the TaN formed with the Xe plasma by applying the RF bias shows more a favorable Cu barrier characteristic compared to the TaN formed without the RF bias. The TaN formed by the sputtering deposition applying the RF bias shows lower nitrogen content, higher crystallinity and stronger Cu barrier characteristics.

The silicon thermally-oxidized film in the example 1 may be a silicon oxide layer in a porous structure. Further, a SiCN film layer may be formed on a porous (porous structure) SiCO as a diffusing barrier layer (S. Grandikota, S. Voss, R. Tao, A. Duboust, D. Cong, L. Y. Chen, S. Ramaswami, D. Carl: Microelectronics Eng. 50 (2000) 547-553). As the permittivity becomes smaller in the porous structure, it is effective for improving the operating characteristics of semiconductor devices. Even in this case, the barrier film can be formed by sputtering Ta with the Xe plasma while avoiding damaging the barrier layer. And the TaN prevents the Cu from diffusing to the interlayer insulator.

### EXAMPLE 2

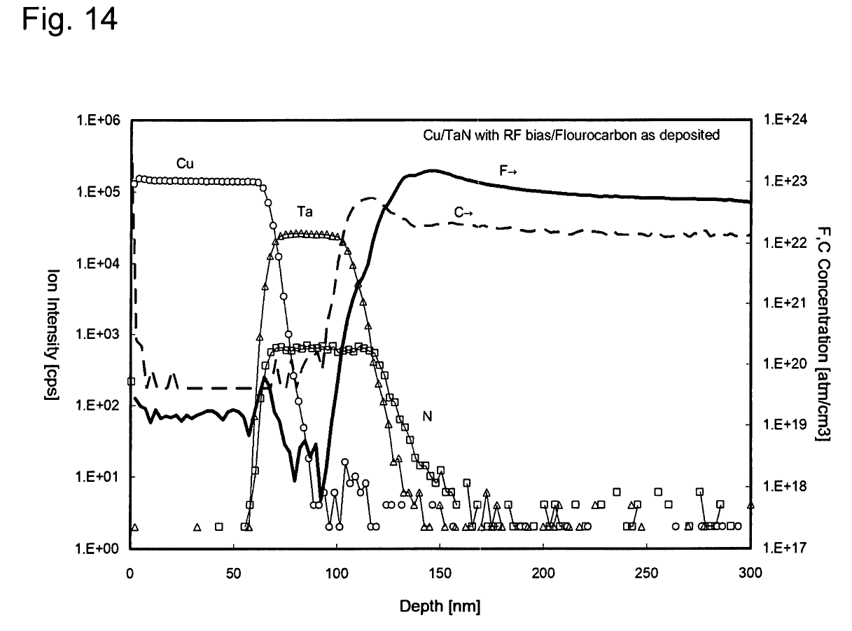

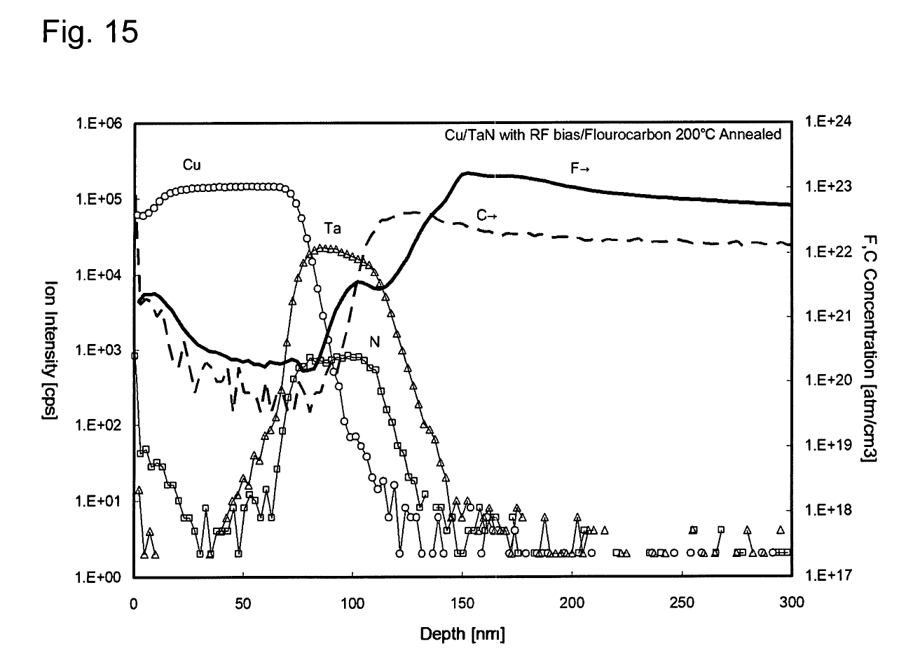

FIGS. 14 and 15 illustrate SIMS analysis in a case when forming Cu on the TaN formed on the fluorocarbon film by applying the RF bias. FIG. 14 is analysis before annealing, and FIG. 15 is the analysis after being annealed at 200° C. In the figures, the solid bold line is the concentration of F, the dashed line is the concentration of C, the white circle is Cu, the white triangle is Ta, and the white square is N. The concentrations of F and C are indicated by the scale on the right (F, C Concentration)(atm/cm³), and intensities of other atoms are indicated by the scale on the left (Ion Intensity)(cps).

As shown in FIG. 14, the F, C and Ta diffuse to the Cu layer; however, the Cu does not diffuse to the TaN layer before and after the annealing. Ta diffuses to Cu after annealing.

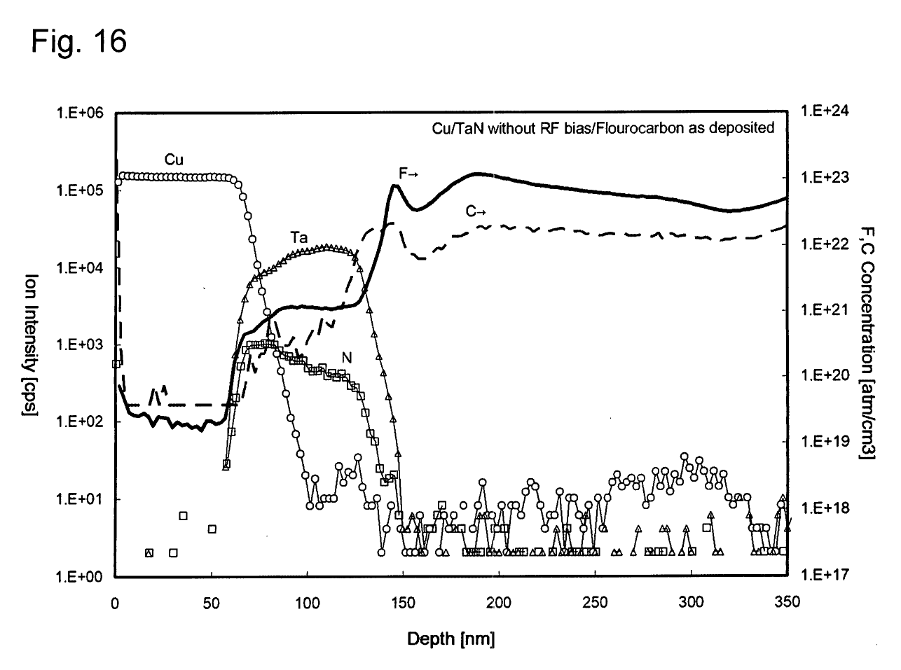

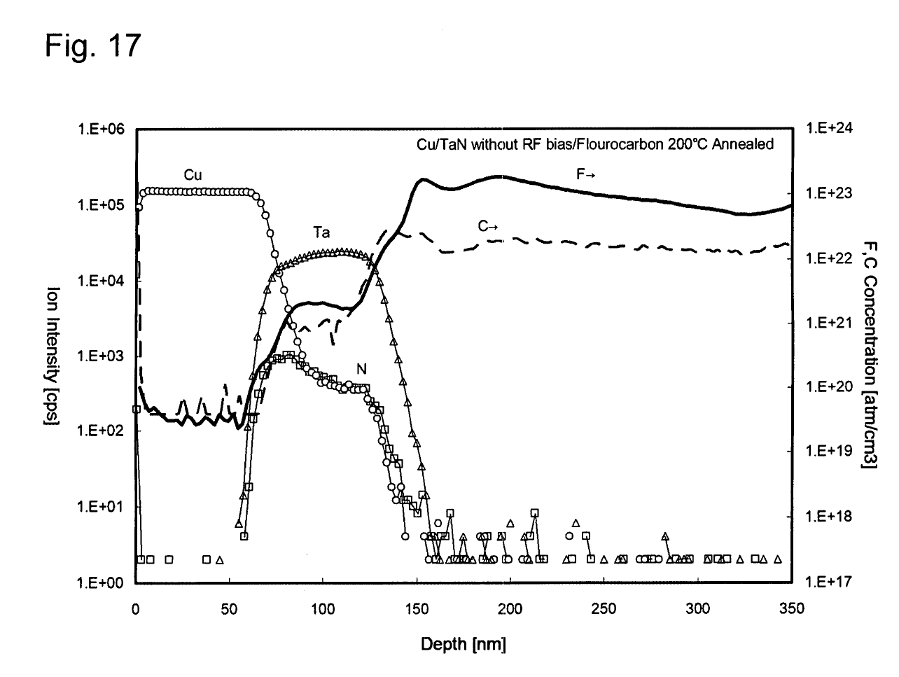

FIGS. 16 and 17 illustrate SIMS analyses in a case when forming Cu on the TaN formed on the fluorocarbon without the RF bias. FIG. 16 is the analysis before the annealing, and FIG. 17 is the analysis after being annealed at 200° C. Each of the symbols and scales are the same as FIG. 14.

F and C atoms exist in the TaN thin film, and are retained in the TaN thin film after annealing. The Cu atom diffuses to the thermally-oxidized silicon film through the fluorocarbon layer. This result is the same as the results of FIGS. 12 and 13. These results show that the Cu atom exists in the TaN after annealing.

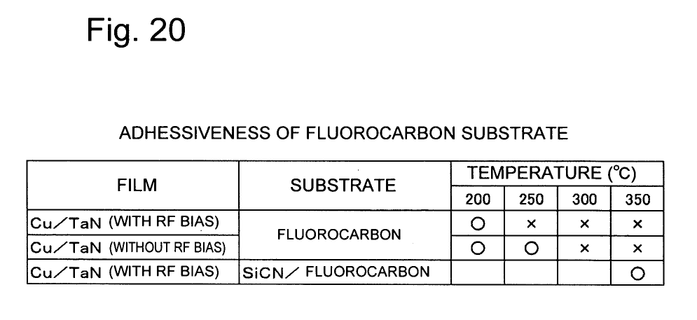

FIG. 20 illustrates an experimental result of adhesiveness of the fluorocarbon substrate. In FIG. 20, “x” shows that the substrate peeled, and “◯” shows that the substrate did not peel. Each of the peels occurred between Cu and TaN. In the TaN and Cu sputtered on the fluorocarbon film by applying the RF bias, the interlayer peeling occurred after being annealed at 250° C. In the TaN sputtered without applying the RF bias, no interlayer peeling occurred even after annealing at a temperature of 300° C. or less.

In the TaN formed by applying the RF bias, the interlayer peeling occurs after being annealed at 250° C. In the TaN formed without applying the RF bias, the interlayer peeling occurs after being annealed at 300° C. These results show that the adhesiveness of TaN sputtered with RF bias and Cu is inferior to the adhesiveness of TaN sputtered without RF bias and Cu after being annealed at 200° C.

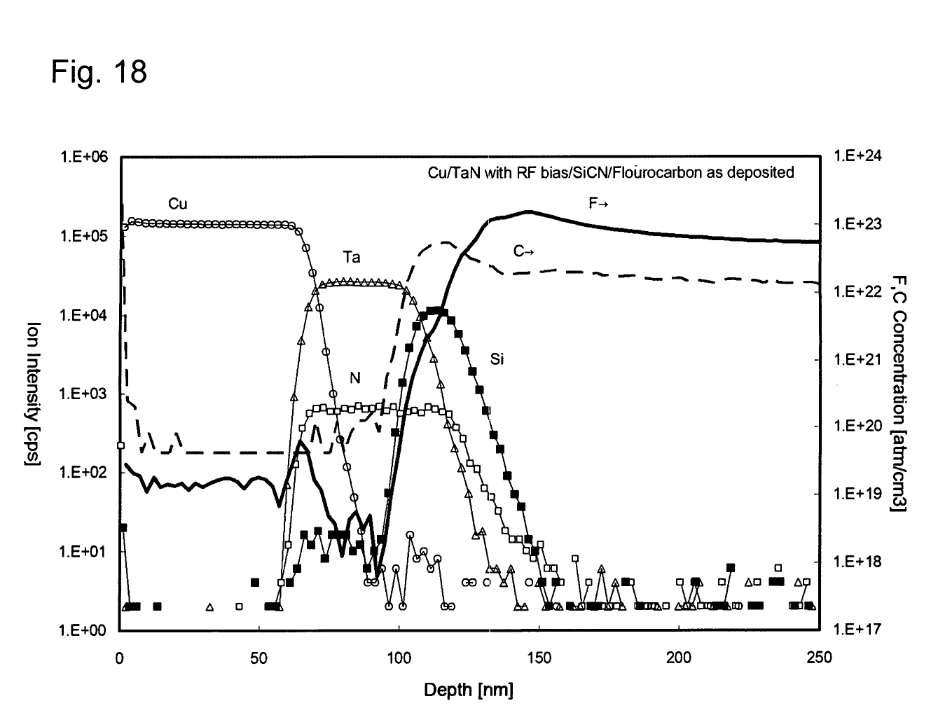

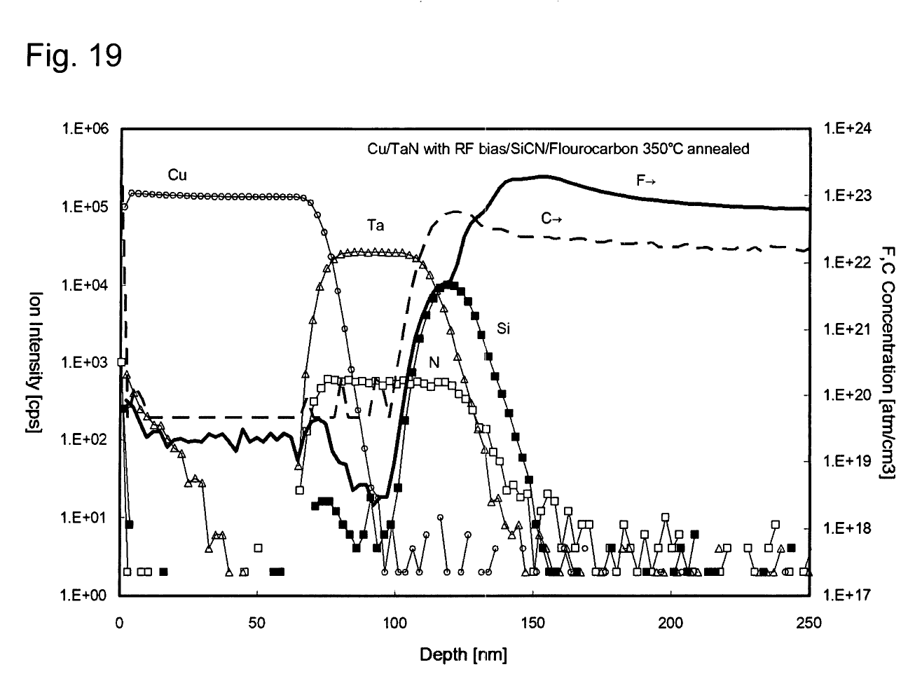

FIGS. 18 and 19 illustrate SIMS analyses in a case when forming Cu on the TaN formed on a silicon carbonitride (SiCN)/fluorocarbon stacked film by applying the RF bias. The barrier film is formed by depositing TaN by Xe sputtering after forming a SiCN layer on an interlayer insulator of fluorocarbon. The wiring layer of Cu is formed on the barrier film.

FIG. 18 shows an analysis before annealing, and FIG. 19 shows an analysis after being annealed at 350° C. In the figures, the bold solid line is the concentration of F, the dashed line is the concentration of C, the white circle is Cu, the white triangle is Ta, the white square is N, and the black square is Si. The concentrations of F and C are indicated by the scale on the right (F, C Concentration)(atm/cm³), and the intensity of other atoms are indicated by the scale on the left.

As shown in FIG. 19, the F and C atoms are not seen in the TaN thin film even after being annealed. This indicates that the SiCN film layer on the fluorocarbon prevents them from diffusing. By referring to FIG. 20, in the TaN formed with the RF bias, the interlayer peeling does not occur even after being annealed at 350° C. This is ascribed to the existence of the SiCN film layer preventing the diffusion of F and C atoms.

In a case when TaN and Cu are formed on the low dielectric constant fluorocarbon material, these results show that the TaN sputtered by applying the RF bias and a SiCN film layer increases the thermal performance of semiconductor devices and is favorable as a manufacturing method.

As described above, the barrier layer of Ta/TaN can be formed by sputtering with a Xe plasma while avoiding damage to an interlayer insulator on a substrate. Especially, it is effective even in the case when the interlayer insulator is a low dielectric constant fluorocarbon because the damage to the interlayer insulator is suppressed.

The barrier property of Ta/TaN against Cu improves by sputtering with a Xe plasma applying the RF bias. The adhesiveness with Cu improves by sputtering the Ta/TaN with a Xe plasma without applying the RF bias. The adhesiveness with Cu can be improved while further improving the barrier property by sputtering the Ta/TaN on the interlayer insulator side by applying the RF bias, and sputtering the Ta/TaN on the wiring layer side without applying the RF bias.

Further, by forming a SiCN film layer on the fluorocarbon layer, which is an interlayer insulator, the diffusion of C and F of the fluorocarbon to the barrier layer of Ta/TaN can be suppressed. The SiCN film layer improves the adhesiveness of the Cu wiring layer and Ta/TaN barrier layer.

The preferred embodiments of the present invention have been explained with reference to the attached figures. Needless to say, the present invention is not limited to those embodiments. It is obvious that one skilled in the art can easily arrive at various changes and modifications within the scope of the claims and it is also understood that those changes and modifications fall within the technical scope of the present invention.

For example, the configurations of the interlayer insulator, barrier film, and wiring layer, and the configuration of the plasma treatment device are just examples and arbitrary changes and modifications can be made.

What is claimed is:

1. A semiconductor device, comprising:
a first layer located over a semiconductor substrate;
a barrier film formed on the first layer, the barrier film comprising tantalum (Ta) and xenon (Xe); and
a second layer located on the barrier film;
where the barrier film suppresses atoms from passing between the first and second layers.

2. The semiconductor device of claim 1, where the first layer is an insulating layer, and the second layer is a conductive layer.

3. The semiconductor device of claim 2, where the second layer comprises copper (Cu).

4. The semiconductor device of claim 2, where the first layer is selected from a group consisting of silicon dioxide (SiO₂), fluorocarbon (CF) and carbon added silicon oxide (SiOC).

5. The semiconductor device of claim 1, further comprising:
a silicon carbonitride (SiCN) layer located between the first layer and the barrier film.

6. The semiconductor device of claim 5, where the first layer comprises fluorocarbon (CF).

7. The semiconductor device of claim 1, where the barrier film comprises:
a lower barrier film portion formed on the first layer by sputtering using a xenon (Xe) gas with an RF bias applied to the semiconductor substrate, the lower barrier film portion comprising a tantalum nitride (TaN); and
an upper barrier film portion formed on the second layer by sputtering using the xenon (Xe) gas without the RF bias applied to the semiconductor substrate or with less RF bias than is applied when forming the lower barrier film portion, the lower barrier film portion comprising a tantalum nitride (TaN).

8. The semiconductor device of claim 1, where the barrier film comprises:
a lower barrier film portion formed on the first layer by sputtering using a xenon (Xe) gas with an RF bias applied to the semiconductor substrate, the lower barrier film portion comprising a tantalum nitride (TaN); and
an upper barrier film portion formed on the second layer by sputtering using the xenon (Xe) gas without the RF bias applied to the semiconductor substrate or with less RF bias than is applied when forming the lower barrier film portion, the lower barrier film portion comprising a tantalum (Ta).

9. A semiconductor device, comprising:
a first insulating layer located over a silicon substrate;
a first interconnection pattern located in the first insulating layer;
a second insulating layer located on the first insulating layer;
at least one via plug located in a lower part of the second insulating layer, the at least one via plug including copper (Cu) and electrically connected to the first interconnection pattern;
a second interconnection pattern located in an upper part of the second insulating layer that includes copper (Cu) and is electrically connected to the at least one via plug; and
a barrier film located between the second insulating layer and the at least one via plug and the second interconnection pattern;
where the barrier film comprises tantalum (Ta) and xenon (Xe).

10. The semiconductor device of claim 9, further comprising:
a silicon carbonitride (SiCN) layer located between the second insulating layer and the barrier film.

11. The semiconductor device of claim 10, where the second insulating layer comprises a low-k material.

12. The semiconductor device of claim 11, where the second insulating layer comprises fluorocarbon (CF).

13. The semiconductor device of claim 9, where the barrier film contains nitrogen (N).

14. The semiconductor device of claim 13, where a number of nitrogen atoms in the barrier film gradually increases through a thickness of the barrier film.

15. A manufacturing method for a semiconductor device, the method comprising the steps of:
forming a first layer over a semiconductor substrate;
forming a barrier film on the first layer that includes tantalum (Ta); and
forming a second layer on the barrier film;
where the barrier film is formed by sputtering using xenon (Xe) gas.

16. The manufacturing method of claim 15, where the barrier film is formed with an RF bias applied to the semiconductor substrate.

17. The manufacturing method of claim 16, where a peak voltage of the RF bias is more than 0V and less than or equal to 20V.

18. The manufacturing method of claim 15, where the first layer comprises fluorocarbon (CF).

19. The manufacturing method of claim 15, further comprising the step of:
forming a silicon carbonitride (SiCN) layer on the first layer after forming the first layer before forming the barrier film.

20. The manufacturing method of claim 15, where forming the barrier film comprises:
forming a lower barrier film on the first layer with an RF bias applied to the semiconductor substrate;
forming an upper barrier film on the lower barrier film without the RF bias applied to the semiconductor substrate or with less RF bias than is applied in forming the lower barrier film to the semiconductor substrate.
